(19) United States
(12) Patent Application Publication
(10) Pub. No.: US 2024/0330788 A1
(43) Pub. Date: Oct. 3, 2024

(54) ANALYSIS AND COMPARISON METHOD OF HOUSEHOLD GAS ENERGY CONSUMPTION BASED ON GAS AMI DATA

(71) Applicant: Korea Electronics Technology Institute, Seongnam-si (KR)

(72) Inventors: Min Su KIM, Seongnam-si (KR); Young Min KWON, Seongnam-si (KR); Seung Woo LEE, Seongnam-si (KR); Seong Seop KIM, Yongin-si (KR)

(73) Assignee: Korea Electronics Technology Institute, Seongnam-si (KR)

(21) Appl. No.: 18/619,387

(22) Filed: Mar. 28, 2024

(30) Foreign Application Priority Data
Mar. 30, 2023 (KR) 10-2023-0042141

(51) Int. Cl. G06Q 10/04; G06Q 50/06

(52) U.S. Cl. CPC G06Q 10/04; G06Q 50/06

(57) ABSTRACT

There is provided a gas AMI data-based household gas energy consumption analysis and comparison method. An energy consumption analysis method according to an embodiment may include: collecting AMI data of a plurality of households; collecting household information of the plurality of households; analyzing energy consumption of each household, based on the collected AMI data; and providing household information of households that have similar energy consumption, based on a result of analyzing. Accordingly, information of other households that use the same/similar energy or have the same/similar energy consumption pattern may be fed back as comparison information, so that efficient use of energy and energy saving may be effectively induced.

### CROSS-REFERENCE TO RELATED APPLICATION(S) AND CLAIM OF PRIORITY

This application is based on and claims priority under 35 U.S.C. § 119 to Korean Patent Application No. 10-2023-0042141, filed on Mar. 30, 2023, in the Korean Intellectual Property Office, the disclosure of which is herein incorporated by reference in its entirety.

### BACKGROUND

### Field

The disclosure relates to energy consumption analysis, and more particularly, to a method for analyzing and comparing household gas energy consumption through machine learning-based gas advanced metering infrastructure (AMI) data analysis to provide an energy efficiency/saving service in an AMI system.

### Description of Related Art

FIG. 1 illustrates example of gas bills currently issued. A gas bill may show current gas charges, usage of this month, gas units used, therm used, etc. to charge for gas energy consumption of each household.

As the need for energy saving and reduction of greenhouse gas is growing, a gas bill may provide, as feedback data, increase/decrease in the amount of gas used compared to the amount used in the last month, comparison of energy consumption by house size, that is, average energy consumption of other households of the same house size, in order to induce reduction of gas energy consumption.

However, such feedback data may be so fragmentary that it does not urge consumers to reduce gas energy consumption. For example, a household that consumes more energy than other households having the same house size may think that there are other factors that cause more energy consumption (for example, the large number of people consumes a lot of gas energy).

Accordingly, there is a need for more realistic and intuitive information for energy saving and efficient energy use. In addition, to solve this, an approach for using gas AMI data collected by an AMI, which is increasingly used in recent years, may be required.

### SUMMARY

The disclosure has been developed in order to solve the above-described problems, and an object of the disclosure is to provide, as a solution for effectively inducing efficient use of energy and energy saving, a method for analyzing gas energy consumption of households through machine learning based on gas AMI data, and feeding back information on other households that use the same/similar energy or have the same/similar energy consumption pattern as comparison information.

To achieve the above-described object, an energy consumption analysis method according to an embodiment of the disclosure may include: collecting AMI data of a plurality of households; collecting household information of the plurality of households; analyzing energy consumption of each household, based on the collected AMI data; and providing household information of households that have similar energy consumption, based on a result of analyzing.

Analyzing may include: grasping past energy consumption of each household based on the collected AMI data; estimating future energy consumption of each household based on the grasped past energy consumption; classifying the households based on the past energy consumption and the future energy consumption; and clustering households that have similar energy consumption in the classified households.

The energy consumption may include an amount of energy used, and providing may include providing household information of households that have a similar amount of energy used. The amount of energy used may be an average amount of energy used during a defined period.

The energy consumption may include an energy consumption pattern, and providing may include providing household information of households that have a similar energy consumption pattern. The household information may include a house size and a number of household members. The household information may further include presence time information.

Clustering may include clustering households that have similar energy consumption and similar household information. The household information may include a house size.

According to another embodiment of the disclosure, an AMI system may include: a collection unit configured to collect AMI data of a plurality of households, and to collect household information of the plurality of households; a storage unit configured to store the collected AMI data; and an analysis unit configured to analyze energy consumption of each household, based on the collected AMI data, and to provide household information of households that have similar energy consumption, based on a result of analyzing.

According to still another embodiment of the disclosure, an energy consumption analysis method may include: transmitting, by AMI meters, AMI data of each household to an energy consumption analysis system; transmitting, by user terminals, household information of each household to the energy consumption analysis system; analyzing, by the energy consumption analysis system, energy consumption of each household, based on the AMI data; and providing, by the energy consumption analysis system, household information of households that have similar energy consumption, based on a result of analyzing.

According to yet another embodiment of the disclosure, an energy consumption analysis system may include: AMI meters configured to transmit AMI data of each household to an energy consumption analysis system; user terminals configured to transmit household information of each household to the energy consumption analysis system; and an energy consumption analysis system configured to analyze energy consumption of each household, based on the AMI data, and to provide household information of households that have similar energy consumption, based on a result of analyzing.

As described above, according to embodiments of the disclosure, gas energy consumption of each household may be analyzed through machine learning based on gas AMI data, and information of other households that use the same/similar energy or have the same/similar energy consumption pattern may be fed back as comparison information, so that efficient use of energy and energy saving may be effectively induced.

Other aspects, advantages, and salient features of the invention will become apparent to those skilled in the art from the following detailed description, which, taken in conjunction with the annexed drawings, discloses exemplary embodiments of the invention.

Before undertaking the DETAILED DESCRIPTION OF THE INVENTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 is a view illustrating examples of existing gas bills;

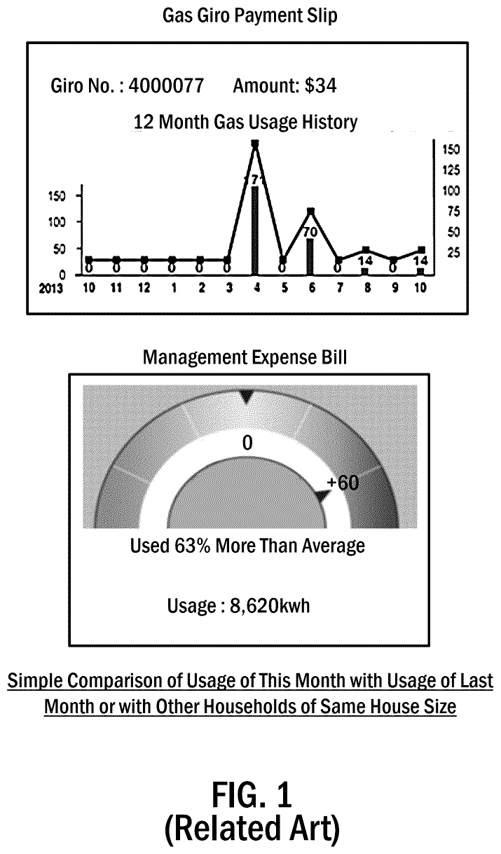

FIG. 2 is a view provided to explain a concept of a method for analyzing and comparing gas energy consumption according to an embodiment;

FIG. 3 is a view illustrating a configuration of an AMI data-based gas consumption analysis/comparison system according to another embodiment;

FIG. 4 is a flowchart provided to explain an AMI data-based gas consumption analysis/comparison method according to still another embodiment;

FIG. 5 is a view schematically illustrating processes of grasping/estimating (regression) an amount of energy used, classifying and clustering based on data analysis;

FIG. 6 is a view illustrating an example of a gas bill which feeds back comparison information with an amount of gas used;

FIG. 7 is a flowchart provided to explain an AMI data-based gas consumption analysis/comparison method according to yet another embodiment of the disclosure; and

FIG. 8 is a view illustrating a configuration of a gas AMI system illustrated in FIG. 3.

### DETAILED DESCRIPTION

Hereinafter, the disclosure will be described in more detail with reference to the accompanying drawings.

Embodiments of the disclosure provide a gas AMI data-based household gas energy consumption analysis and comparison method.

The disclosure relates to a technology of feeding back information on other households using the same/similar energy as comparison information, rather than providing information on increase/decrease in the amount of gas used compared to the amount used in the last month or comparison of energy consumption by house size, in order to induce efficient use of energy and energy saving.

To achieve this, analyzing gas energy consumption of each household through machine learning based on gas AMI data may be required. Furthermore, it is possible to feed back information on other households having the same/similar energy consumption pattern.

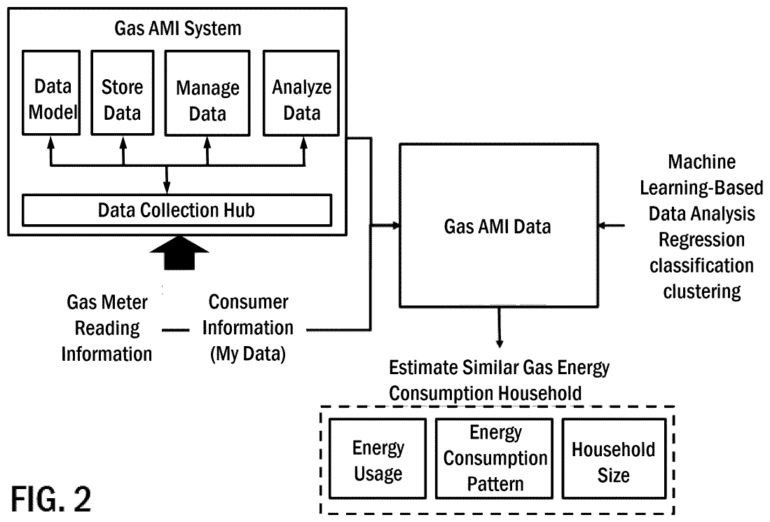

FIG. 2 is a view provided to explain a concept of a gas energy consumption analysis and comparison method according to an embodiment of the disclosure.

To analyze/compare gas energy consumption, a gas AMI system should collect and store gas AMI data from gas meters (AMI meters), and should collect and store household (consumer) information from respective households (consumers).

The gas AMI data may include data that is needed to calculate and estimate an amount of gas energy used, such as a reading time, a resettable total, a flow rate, temperature, pressure, etc. The household information may include data that is needed to identify households and compare current statuses of gas energy consumption, such as a residence location, a house size, household size information (the number of household members), amount paid, a data storage period, etc.

The gas AMI system may feed back, as comparison information, information on other households that use the same or similar energy through machine learning (regression, classification, clustering)-based gas AMI data analysis.

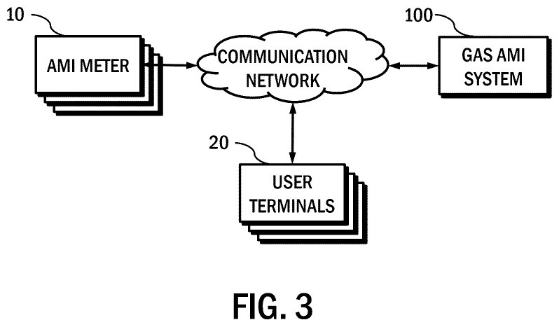

FIG. 3 is a view illustrating a configuration of an AMI data-based gas consumption analysis/comparison system according to another embodiment of the disclosure. The gas consumption analysis/comparison system according to an embodiment of the disclosure may include AMI meters 10, user terminals 20, and a gas AMI system 100 as shown in FIG. 3.

The AMI meters 10 may generate AMI data and may periodically transmit AMI data to the gas AMI system 100 through a communication network. The AMI data refers to data for calculating gas energy consumption.

The user terminals 20 may receive household information from users and may transmit household information to the gas AMI system through the communication network. The user terminals 20 may be implemented by personal computers (PCs), smartphones, wall pads of users. Regarding the embodiments of the disclosure, household information should specify households, and should include house sizes, household sizes (the number of household members) in addition to information needed to charge.

The gas AMI system 100 may collect/store AMI data transmitted from the AMI meters 10 and household information transmitted from the user terminal 20, and may hold the information. The household information may be required to undergo a de-identification and user confirmation/authentication procedure to be protected before it is stored.

In addition, the gas AMI system 100 may analyze collected/stored data based on machine learning, may generate, as comparison information, information on other households that use the same/similar energy or information on other household that have the same/similar energy consumption pattern, and may feed back to the user terminals 20 through the communication network. The comparison information may be included in a gas bill and may be fed back to users.

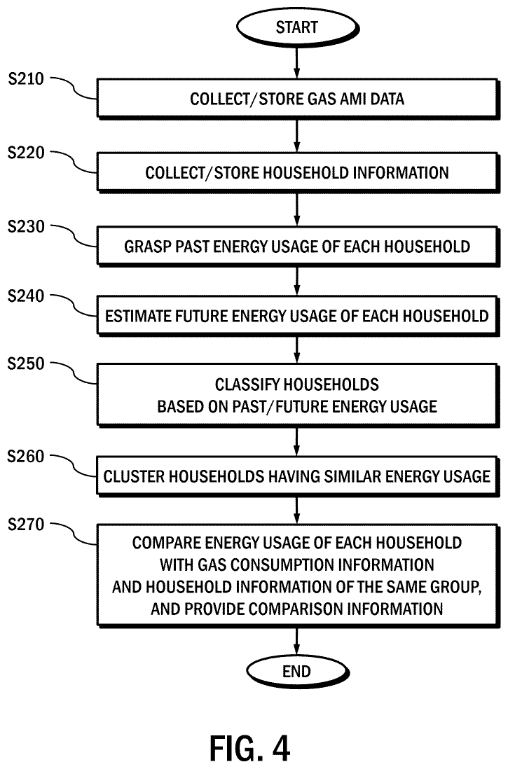

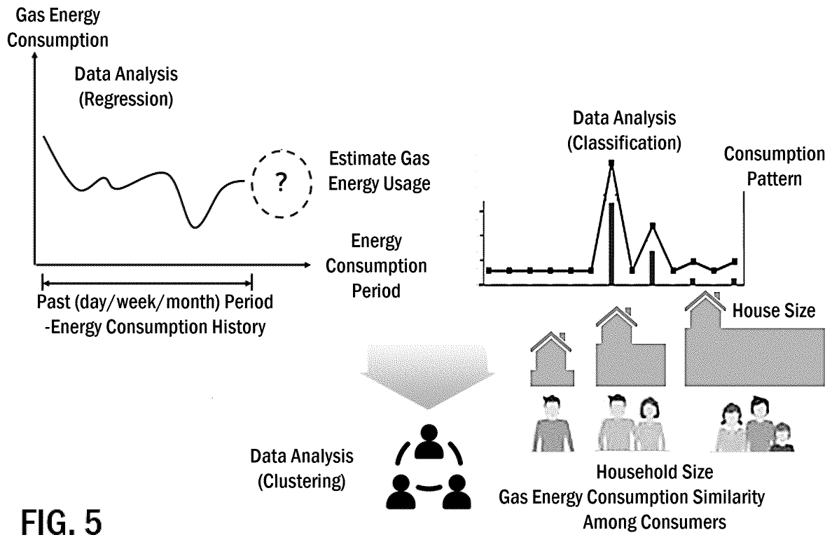

Hereinafter, a gas consumption analysis/comparison process performed by the system described above will be described in detail with reference to FIGS. 4 and 5. FIG. 4 is a flowchart provided to explain an AMI data-based gas consumption analysis/comparison according to still another embodiment of the disclosure.

As shown in FIG. 4, the gas AMI system 100 may collect and store gas AMI data from the AMI meters 10 installed in respective houses (S210), and may collect and store household information from the user terminals 20 (S220). Step S210 may be periodically performed but step S220 may be performed only when necessary, for example, when household information is added, changed, or deleted.

The gas AMI system 100 may analyze energy consumption of each household, based on data collected at step S210 and step S220 (S230 to S260). A detailed process will be described hereinbelow.

The gas AMI system 100 may grasp past energy usage of each household from the collected gas AMI data (S230), and may estimate future energy usage of each household through machine learning based on the grasped past energy usage (S240). At step S240 of estimating, regression analysis, a deep learning model may be used.

The gas usage grasped and estimated at step S230 and step S240 may be defined as average gas usage measured during a defined period, for example, days, week, month, year.

The gas AMI system 100 may classify households based on the past energy usage grasped at step S230 and the future energy usage estimated at step S240 (S250), and may cluster households that have similar energy usage in the classified households (S260).

To this end, households that have similar gas usage may be clustered into the same group. FIG. 5 schematically illustrates an energy usage grasping/estimating (regression), classifying, and clustering process based on data analysis.

The gas AMI system 100 may compare energy usage of each household with gas consumption information and household information of the group to which a corresponding household belongs, based on the result of analysis, and may provide comparison information (S270).

The gas consumption information provided may include an average consumption pattern of households included in the same group, and the household information may include the average number of household members and an average house size of the households included in the same group.

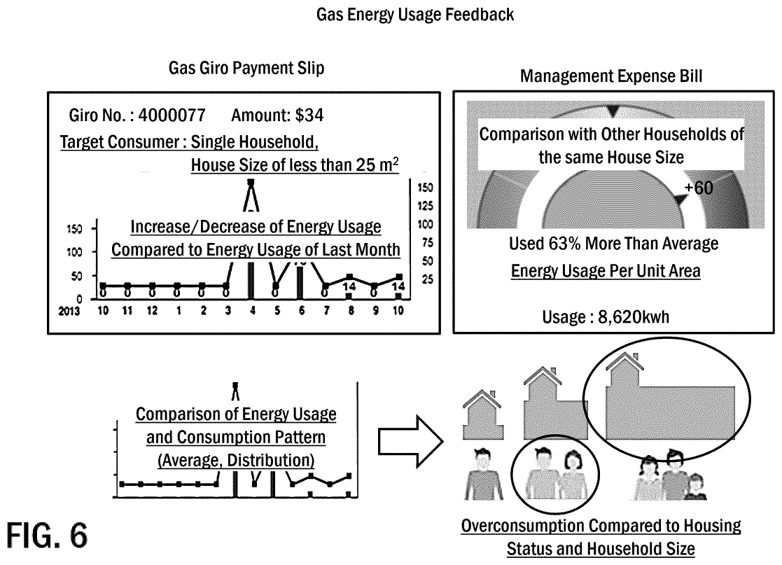

FIG. 6 illustrates an example of a gas bill which feeds back a gas consumption pattern, an average house size, and the number of household members of households belonging to the same group, which correspond to comparison information, along with gas usage.

Through this bill, each household may know the gas consumption pattern of households having similar gas usage to its own gas usage, and may know the number of household members and the house size. If the household receiving the gas bill as shown in FIG. 6 is a single household of a house size of 19.5 m², the household identifies that the house size of the household using the same energy is 27.6 m² and the number of household members is two people, and recognizes that the corresponding household consumed a lot of gas compared to the house size and the number of household members of other households.

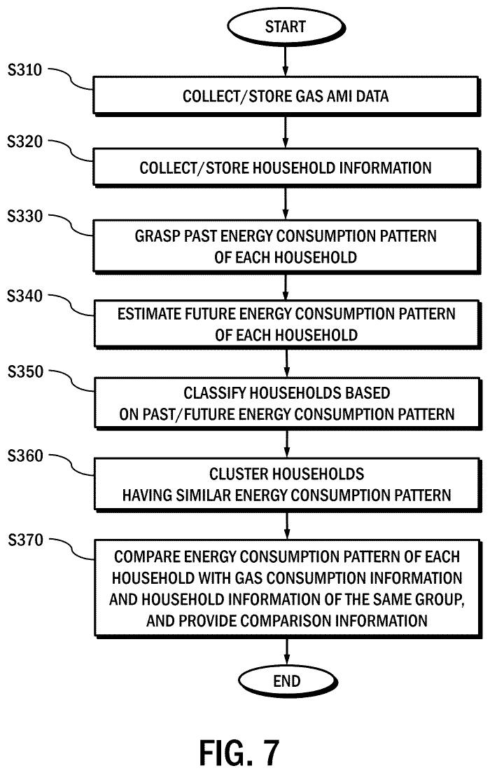

FIG. 7 is a flowchart provided to explain an AMI data-based gas consumption analysis/comparison method according to still another embodiment of the disclosure.

As shown in FIG. 7, the gas AMI system 100 may collect and store gas AMI data from the AMI meters 10 installed in respective houses (S310), and may collect and store household information from the user terminals 20 (S320).

The gas AMI system 100 may grasp a past energy consumption pattern of each household from the collected gas AMI data (S330), and may estimate a future energy consumption pattern of each household based on the grasped past energy consumption pattern (S340).

The gas AMI system 100 may classify households based on the past energy consumption pattern grasped at step S330 and the future energy consumption pattern estimated at step S340 (S350), and may cluster households having similar energy consumption patterns in the classified households (S360). Accordingly, households having similar gas consumption patterns may be clustered into the same group.

The gas AMI system 100 may compare an energy consumption pattern of each household with gas consumption information and household information of the group to which a corresponding household belongs, based on the result of analysis, and may provide comparison information (S370).

The gas consumption information provided may include average usage of households included in the same group, and the household information may include the average number of household members and an average house size of the households included in the same group.

Through this, each household may know the gas usage of households having similar gas consumption patterns to its own gas consumption pattern, and may know the number of household members and the house size.

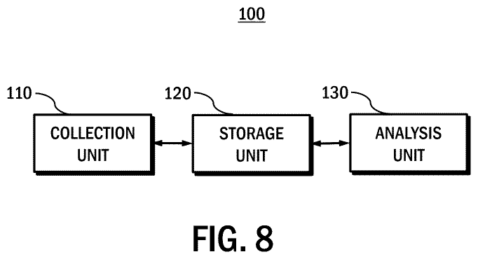

FIG. 8 is a view illustrating a configuration of the gas AMI system 100 illustrated in FIG. 3. As shown in FIG. 8, the gas AMI system 100 may include a collection unit 110, a storage unit 120, and an analysis unit 130.

The collection unit 110 may collect AMI data transmitted from the AMI meters 10, and household information transmitted from the user terminals 20, and may store collected data in the storage unit 120.

The analysis unit 130 may analyze data stored in the storage unit 120 based on machine learning, may generate comparison information including information on other households using the same/similar energy or information on other households showing the same energy consumption pattern, and may feed back the comparison information to the user terminals 20 through a communication network.

Up to now, a gas AMI data-based household gas energy consumption analysis and comparison method has been described with reference to preferred embodiments.

In the above embodiments, it is assumed that households are classified/clustered with reference to gas energy usage and a gas energy consumption pattern, but this is merely an example and changes may be made thereto.

Furthermore, multiple criteria may be applied. For example, households that have the same energy usage and the same house size may be clustered and the number of household members may be provided as comparison information. In another example, households that have the same gas energy consumption pattern and the same house size may be clustered and the number of household members may be provided as comparison information.

In the above embodiments, comparison information fed back may also be an example and changes may be made thereto. For example, presence time information of other households having the same gas energy usage and the same house size may be fed back or presence time information of other households having the same gas energy consumption pattern and the same house size may be fed back. As the presence time information, total presence time, presence time in each time zone (forenoon/afternoon/night) may be applied. In this case, however, presence time information may be required to be collected/stored in advance as household information.

Accordingly, by providing a household with a similar gas energy consumption household prediction result obtained through machine learning-based gas AMI data analysis as feedback data, gas energy saving of the household may be effectively induced in terms of energy efficiency/saving service.

In addition, an energy efficiency/saving service may be designed and developed by using gas AMI data in consideration of various characteristics, such as a residence location, energy usage, an energy consumption pattern, household information of a household.

In the above embodiments, gas energy has been explained, but this is merely an example for the convenience of explanation. The technical concept of the disclosure may be applied to other energy than gas energy, for example, electricity energy, heating energy, water energy.

The technical concept of the disclosure may be applied to a computer-readable recording medium which records a computer program for performing the functions of the apparatus and the method according to the present embodiments. In addition, the technical idea according to various embodiments of the disclosure may be implemented in the form of a computer readable code recorded on the computer-readable recording medium. The computer-readable recording medium may be any data storage device that can be read by a computer and can store data. For example, the computer-readable recording medium may be a read only memory (ROM), a random access memory (RAM), a CD-ROM, a magnetic tape, a floppy disk, an optical disk, a hard disk drive, or the like. A computer readable code or program that is stored in the computer readable recording medium may be transmitted via a network connected between computers.

In addition, while preferred embodiments of the present disclosure have been illustrated and described, the present disclosure is not limited to the above-described specific embodiments. Various changes can be made by a person skilled in the at without departing from the scope of the present disclosure claimed in claims, and also, changed embodiments should not be understood as being separate from the technical idea or prospect of the present disclosure.

What is claimed is:

1. An energy consumption analysis method comprising:
collecting AMI data of a plurality of households;
collecting household information of the plurality of households;
analyzing energy consumption of each household, based on the collected AMI data; and
providing household information of households that have similar energy consumption, based on a result of analyzing.

2. The energy consumption analysis method of claim 1, wherein analyzing comprises:
grasping past energy consumption of each household based on the collected AMI data;
estimating future energy consumption of each household based on the grasped past energy consumption;
classifying the households based on the past energy consumption and the future energy consumption; and
clustering households that have similar energy consumption in the classified households.

3. The energy consumption analysis method of claim 2, wherein the energy consumption includes an amount of energy used, and wherein providing comprises providing household information of households that have a similar amount of energy used.

4. The energy consumption analysis method of claim 3, wherein the amount of energy used is an average amount of energy used during a defined period.

5. The energy consumption analysis method of claim 2, wherein the energy consumption includes an energy consumption pattern, and wherein providing comprises providing household information of households that have a similar energy consumption pattern.

6. The energy consumption analysis method of claim 3, wherein the household information includes a house size and a number of household members.

7. The energy consumption analysis method of claim 5, wherein the household information includes a house size and a number of household members.

8. The energy consumption analysis method of claim 6, wherein the household information further includes presence time information.

9. The energy consumption analysis method of claim 7, wherein the household information further includes presence time information.

10. The energy consumption analysis method of claim 2, wherein clustering comprises clustering households that have similar energy consumption and similar household information.

11. The energy consumption analysis method of claim 10, wherein the household information includes a house size.

12. An AMI system comprising:
a collection unit configured to collect AMI data of a plurality of households, and to collect household information of the plurality of households;
a storage unit configured to store the collected AMI data; and
an analysis unit configured to analyze energy consumption of each household, based on the collected AMI data, and to provide household information of households that have similar energy consumption, based on a result of analyzing.

13. An energy consumption analysis method comprising:
transmitting, by AMI meters, AMI data of each household to an energy consumption analysis system;
transmitting, by user terminals, household information of each household to the energy consumption analysis system;
analyzing, by the energy consumption analysis system, energy consumption of each household, based on the AMI data; and
providing, by the energy consumption analysis system, household information of households that have similar energy consumption, based on a result of analyzing.
